(19) United States
(12) Patent Application Publication
(10) Pub. No.: US 2017/0323871 A1
(43) Pub. Date: Nov. 9, 2017

(54) LIGHT-EMITTING DIODE DISPLAY APPARATUS

(71) Applicant: EVERLIGHT ELECTRONICS CO., LTD., New Taipei City (TW)

(72) Inventors: Yi-Ping Yeh, New Taipei City (TW); Chia-Fong Chou, New Taipei City (TW); Wei-Ting Wu, New Taipei City (TW)

(73) Assignee: EVERLIGHT ELECTRONICS CO., LTD., New Taipei City (TW)

(21) Appl. No.: 15/586,304

(22) Filed: May 4, 2017

Related U.S. Application Data
(60) Provisional application No. 62/331,984, filed on May 5, 2016.
(60) Provisional application No. 62/335,025, filed on May 11, 2016.

(51) Int. Cl. H01L 25/13; G09G 3/32; H01L 33/48

(52) U.S. Cl. CPC H01L 25/13; H01L 33/483; G09G 3/32; G09G 2300/0408; G09G 2320/0233

(57) ABSTRACT

A light-emitting diode display apparatus including a circuit substrate, a display matrix, a driving circuit, and an interface circuit is provided. The display matrix is disposed on the circuit substrate, and has a plurality of display pixels. The driving circuit is disposed on the circuit substrate, and has at least one driver. The driver has a programmable planning area. The interface circuit is disposed on the circuit substrate, and electrically coupled to the driving circuit. The interface circuit is configured to receive input information, and transports the input information to the driving circuit.

### CROSS-REFERENCE TO RELATED APPLICATION

This application claims the priority benefits of U.S. provisional application Ser. No. 62/331,984, filed on May 5, 2016, and U.S. provisional application Ser. No. 62/335,025, filed on May 11, 2016. The entirety of each of the above-mentioned patent applications is hereby incorporated by reference herein and made a part of specification.

### BACKGROUND OF THE INVENTION

### Field of the Invention

The invention relates to a light-emitting diode (LED) display apparatus, and particularly relates to a LED display apparatus capable of simplifying a system design and increasing a fill factor of a light-emitting area.

### Description of Related Art

In the conventional technical field, along with miniaturization of the size of light-emitting diodes (LED), it is no longer difficult to display high resolution fine images through a LED display apparatus. However, along with increase of display pixels on a display panel, in order to effectively control all of the display pixels, a large amount of transmission lines used for transmitting driving signals are required. In this case, a client end has to deal with a complex layout of the large amount of transmission lines and signal interferences probably generated therebetween in system design, which causes a great burden.

On the other hand, in the conventional LED display apparatus, regarding a problem of contrast reduction due to a solder paste on the LEDs, a mask or a black adhesive is generally adhered to a periphery of the LEDs to improve the contrast. However, since the mask occupies a part of area of the LED panel, a ratio (a fill factor) of a light-emitting area and a total area of the LED panel is decreased, which probably causes a phenomenon of bright spot or image discontinuity.

### SUMMARY OF THE INVENTION

The invention is directed to a light-emitting diode (LED) display apparatus, which is adapted to simplify a burden of system design of a client end.

The invention is directed to a LED display apparatus, which is adapted to increase a fill factor of a light-emitting area of a display panel.

The invention provides a LED display apparatus including a circuit substrate, a display matrix, a driving circuit, and an interface circuit. The display matrix is disposed on the circuit substrate, and has a plurality of display pixels. The driving circuit is disposed on the circuit substrate and is electrically coupled to the display matrix. The driving circuit has at least one driver. The driver has a programmable planning area. The interface circuit is disposed on the circuit substrate, and is electrically coupled to the driving circuit. The interface circuit is configured to receive input information, and transports the input information to the driver.

In an embodiment of the invention, the circuit substrate has a first surface and a second surface opposite to each other. The display matrix is disposed on the first surface of the circuit substrate, and the driving circuit and the interface circuit are disposed on the second surface of the circuit substrate.

In an embodiment of the invention, the interface circuit is a serial interface circuit.

In an embodiment of the invention, each of the display pixels emits a monochromatic light or a polychromatic light.

In an embodiment of the invention, each of the display pixels includes at least one light-emitting diode (LED). The at least one LED has at least one light-emitting wavelength.

In an embodiment of the invention, the LED is a flip-chip package, a surface mounted device, a epoxy molding compound lead frame, a chip scale package or a chip on board package.

In an embodiment of the invention, the driver includes at least one horizontal driver or at least one vertical driver.

In an embodiment of the invention, each of the display pixels includes a package base. The package base has a first surface and a second surface opposite to each other. The first surface of the package base is configured with LEDs with at least one light-emitting wavelength. The second surface of the package base is bonded to the circuit board, where an area of the first surface of the package base is greater than or equal to an area of the second surface of the package base.

In an embodiment of the invention, a projection of the first surface of the package base on the circuit board completely covers the second surface of the package base.

In an embodiment of the invention, the second surface of the package base is bonded to the circuit substrate through a conductive adhesive material.

The invention provides another light-emitting diode (LED) display apparatus including a circuit substrate, a display matrix, a driving circuit, and an interface circuit. The display matrix is disposed on the circuit substrate, and has a plurality of display pixels. Each of the display pixels includes a package base, the package base has a first surface and a second surface opposite to each other. The first surface of the package base is configured with LEDs with at least one light-emitting wavelengths. The second surface of the package base is bonded to the circuit board, where an area of the first surface of the package base is greater than or equal to an area of the second surface of the package base. The driving circuit is disposed on the circuit substrate and includes a plurality of drivers to drive the display pixels, where each of the drivers includes a programmable planning area. The interface circuit is disposed on the circuit substrate, and is electrically coupled to the driving circuit.

According to the above description, in the LED display apparatus of the invention, the programmable planning area is configured on the driving circuit, and input information is received through the interface circuit, and related information of driving mode is stored in the programmable planning area. The driver executes operations of the display pixels through the information recorded in the programmable planning area, so as to simplify a system design of a client end. In the design of the display pixels, the first surface of the package base carrying the LED covers the second surface of the package base bonded to the circuit substrate, so as to improve a contrast of the LED display apparatus, and decrease a distance between the LED elements to increase a fill factor of the display area.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a schematic diagram of a light-emitting diode (LED) display apparatus according to an embodiment of the invention.

FIG. 2 is a structural schematic diagram of the LED display apparatus according to an embodiment of the invention.

FIG. 3A and FIG. 3B are schematic diagrams of a driving method of the

LED display apparatus according to an embodiment of the invention.

FIG. 4 is a structural schematic diagram of a display pixel according to an embodiment of the invention.

FIG. 5 is a schematic diagram of a display matrix according to an embodiment of the invention.

### DESCRIPTION OF EMBODIMENTS

Referring to FIG. 1, FIG. 1 is a schematic diagram of a light-emitting diode (LED) display apparatus according to an embodiment of the invention. The LED display apparatus 100 includes a circuit substrate 110, a display matrix 120, a driving circuit 130, and an interface circuit 140. The display matrix 120 is disposed on the circuit substrate 110, and has a plurality of display pixels formed by LEDs. The driving circuit 130 is also disposed on the circuit substrate 110, and is electrically coupled to the display matrix 120. The driving circuit 130 provides a driving signal to drive the display matrix 120 to perform an image display function. The interface circuit 140 is disposed on the circuit substrate 110, and is electrically coupled to the driving circuit 130. The interface circuit 140 is configured to receive input information INF, and transports the input information INF to the driving circuit 130.

On the other hand, the driving circuit 130 includes one or a plurality of drivers 131-13N. In the present embodiment, the driver 131 is electrically coupled to the interface circuit 140, and the drivers 131-13N are connected in series. Moreover, each of the drivers 131-13N may include a programmable planning area for storing driving information related to each of the drivers 131-13N.

In view of operation, a user may input the driving information related to each of the drivers 131-13N through the interface circuit 140. The driving information can be received by the interface circuit 140 through the input information INF, and can be sequentially transmitted to each of the drivers 131-13N. Each of the drivers 131-13N may store the received related driving information in the programmable planning area, respectively. In case of a display operation, the drivers 131-13N may respectively decode the driving information in the programmable planning areas, and generate driving signals to drive the display matrix 120 to display.

It should be noted that in an embodiment that the drivers 131-13N decode the driving information in the programmable planning areas, the programmable planning areas may store information related to the decoding operation, for example, program codes of the decoding operation. In this way, the drivers 131-13N may read and execute the program codes of the decoding operation in the programmable planning areas to decode the driving information, and further generate the driving signals.

It should be noted that the interface circuit 140 can be a serial interface circuit, for example, a universal serial bus (USB), a serial peripheral interface (SPI), or a communication interface of optical communication, wireless communication or inter-integrated circuit (I²C), or can be any other communication interface known by those skilled in the art and any communication interface within 8 pins, which is not limited by the invention. The circuit substrate 110 can be a semiconductor material (for example, gallium arsenide) substrate containing silicon or other materials, a printed circuit board (PCB), a metal core printed circuit board (MCPCB), a FR-4 PCB, a silicon copper base substrate, a glass substrate, a sapphire substrate, a flexible circuit board, a substrate made of transparent or opaque materials such as polyethylene terephathalate (PET), polypropylene (PP), polyimide (PI), polymethylmethacrylate (PMMA), etc., or any type of a package substrate suitable for the art.

According to the above description, it can be known that under the structure of the LED display apparatus 100 of the present embodiment, the client is only required to perform system design on relative less pin number of the interface circuit 140, which greatly decreases complexity of the system design and probability of generated signal interference, so as to improve the whole efficiency of the LED display apparatus 100.

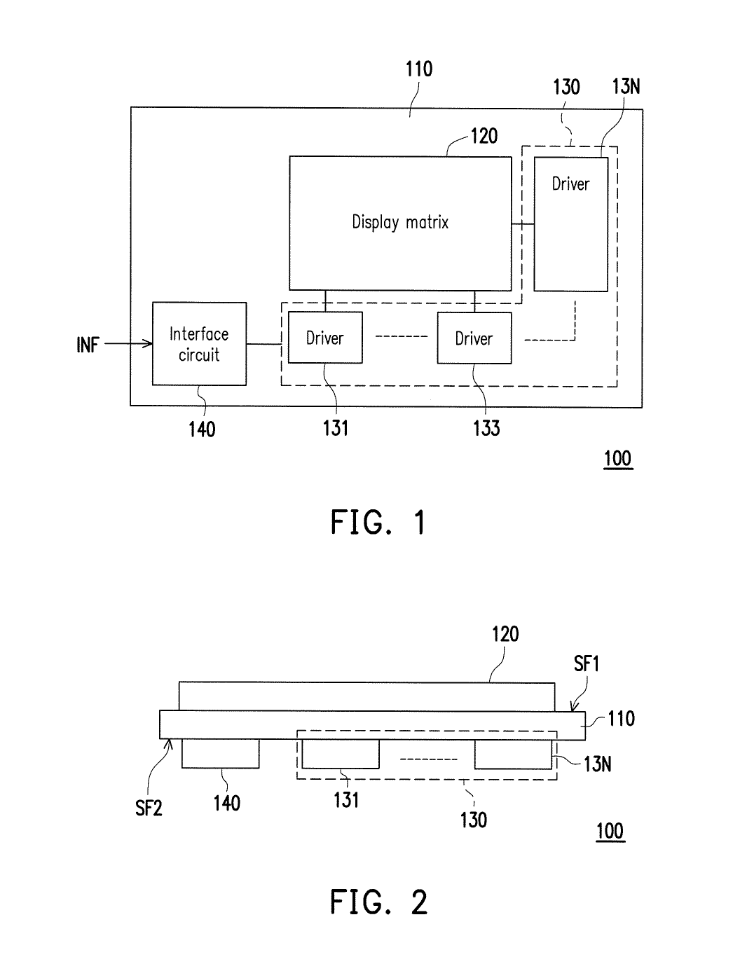

Referring to FIG. 2, FIG. 2 is a structural schematic diagram of the LED display apparatus according to an embodiment of the invention. In FIG. 2, the circuit substrate 110 has two surfaces SF1 and SF2 opposite to each other. The display matrix 120 is disposed on the surface SF1 of the circuit substrate 110, and the driving circuit 130 and the interface circuit 140 are commonly disposed on the surface SF2 opposite to the surface SF1. In the present embodiment, the driving circuit 130 and the interface circuit 140 can be electrically connected through wires on the surface SF2, and the driving circuit 130 can be electrically connected to the display matrix 120 through a conductive through via in the circuit substrate 110. The drivers 131-13N in the driving circuit 130 and the interface circuit 140 can be a plurality of integrated circuits (ICs).

It should be noted that ICs of different functions can be configured on the surface SF2 of the circuit substrate 110, for example, a power management chip. The point is that by configuring a plurality of ICs on the surface SF2 of the circuit substrate 110, a size of the circuit substrate 110 is decreased without influencing a display area of the display matrix 120.

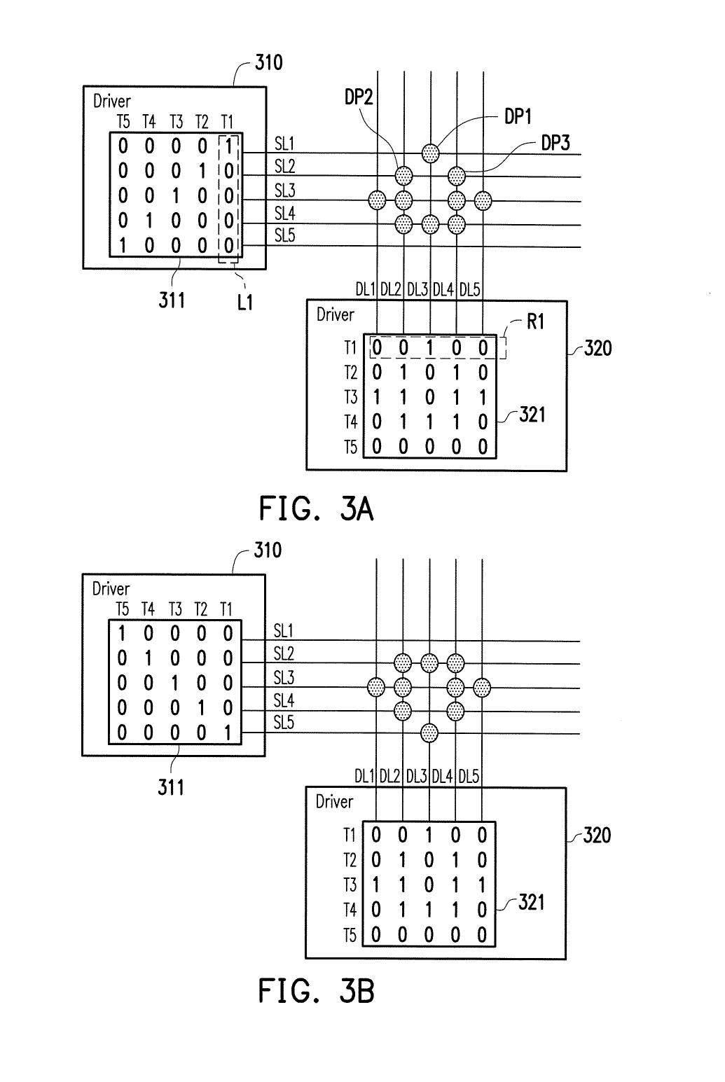

Referring to FIG. 3A and FIG. 3B, FIG. 3A and FIG. 3B are schematic diagrams of a driving method of the LED display apparatus according to an embodiment of the invention. In FIG. 3A, the driver 310 and the driver 320 include a programmable planning area 311 and a programmable planning area 321, respectively. The driver 310 can be a vertical driver used for driving scan lines SL1-SL5 on the display matrix, and the driver 320 can be a horizontal driver used for driving data lines DL1-DL5 on the display matrix.

The programmable planning area 311 and the programmable planning area 321 record driving information related to the driver 310 and the driver 320, respectively. The driving information in the programmable planning area 311 records the scan lines SL1-SL5 respectively driven by a plurality of driving timings T1-T5, and the driving information in the programmable planning area 321 records the data lines DL1-DL5 respectively driven by the driving timing T1-T5. In detail, at the driving timing T1, the driver 310 reads information L1 corresponding to the driving time T1 in the driving information, and drives the scan line SL1 corresponding to a bit “1” in the information L1. Meanwhile, the driver 320 reads information R1 corresponding to the driving time T1 in the driving information, and drives the data line DL3 corresponding to the bit “1” in the information R1. In this way, the display pixel DP1 electrically coupled to the scan line SL1 and the data line DL3 is lighted.

Then, at the driving timing T2, the drivers 310 and 320 respectively drive the scan line SL2 and the data lines DL2 and DL4 according to the driving information corresponding to the driving timing T2 in the programmable planning areas 311 and 321, and light the display pixels DP2 and DP3.

Deduced by analogy, the drivers 310 and 320 may drive the scan lines SL1-SL5 and the data lines DL1-DL5 according to the driving information corresponding to different driving timings T1-T5 in the programmable planning areas 311 and 321, and drive the display matrix to execute corresponding image display operations.

It should be noted that the driving information in the programmable planning area is changeable. In FIG. 3B, the driving information in the programmable planning area 311 of the driver 310 is different to that shown in FIG. 3A. To be specific, in the driving information in the programmable planning area 311 of FIG. 3B, the corresponding relationship between the driving times T1-T5 and the scan lines SL1-SL5 is inversed to that in the driving information in the programmable planning area 311 of FIG. 3A. Therefore, a display image generated by the display matrix driven by the drivers 310 and 320 of FIG. 3B is a horizontal flip image of the display image of FIG. 3A.

Certainly, the driving information in the programmable planning area 321 of the driver 320 can also be adjusted, such that the display image generated by the display matrix is accordingly adjusted. In other embodiments of the invention, the driver 310 may synchronously drive a plurality of scan lines to display in a same driving timing.

Moreover, the method of controlling lighting of the display pixel through a single bit “1” or “0” of the aforementioned embodiment can be adjusted to control lighting of the display pixel through information of a plurality of bits in other embodiment of the invention. In this way, through information of a plurality of bits, besides it is controlled whether the display pixel is lighted, a brightness and/or a color of the display pixel can also be controlled.

It should be noted that the drivers 310 and 320 can be constructed by processors having computation capability, and the programmable planning areas 311 and 321 can be constructed by any type of memories. The drivers 310 and 320 may respectively read the driving information in the programmable planning areas 311 and 321 to drive the scan lines SL1-SL5 and the data lines DL1-DL5, so as to drive the display matrix to generate the display image.

In other embodiment of the invention, a data size of the driving information can be reduced through a coding manner for storing in the programmable planning area. In this way, the driver may first decode the read driving information, and drive the display matrix according to the decoded driving information.

On the other hand, when the display matrix is driven, the driven scan line may provide a relatively high voltage to an anode of the LED (the display pixel), and the driven data line may provide a relatively low voltage to a cathode of the LED (the display pixel), so as to drive the display pixel to emit light. Certainly, in case of another configuration, when the display matrix is driven, the driven scan line may provide a relatively low voltage to the cathode of the LED (the display pixel), and the driven data line may provide a relatively high voltage to the anode of the LED (the display pixel), so as to drive the display pixel to emit light. It should be noted that each of the display pixels is composed of LED chips of three colors (three chips) of red, green and blue (RGB), or composed of LED chips of four colors (four chips) of red, green, blue and white (RGBW) in response to a high color saturation and color rendering index, so that white balance and maximum expected brightness can be achieved by adjusting a LED current, or gray scales are achieved through a dimming method. An applicable dimming technique is, for example, pulse width modulation (PWM) dimming, TRIAC dimming, wireless dimming, remote control dimming, digital-to-analog conversion (DAC) dimming and linear dimming, etc. Therefore, the invention is not only adapted to a strong light environment (for example, a vehicle head-up display apparatus), a problem of excessive light intensity of the display apparatus in the night-time is also mitigated (for example, a night-time billboard).

The embodiments of FIG. 3A and FIG. 3B are only examples, and the structure of the LED display apparatus of the invention is not limited thereto. The LED display apparatus of the invention may expand pixel points of the display image by splicing a plurality of horizontal drivers and a plurality of vertical drivers. Meanwhile, when a driver of the display apparatus fails, only the display module with the problem is required to be replaced, and it is unnecessary to replace the entire panel or billboard due to extra parts connected between the failed driver and the matrix display panel, which effectively decreases maintenance cost of the LED display apparatus. Moreover, by dynamically adjusting the driving information in the horizontal drivers and the vertical drivers, the LED display apparatus may display dynamic images.

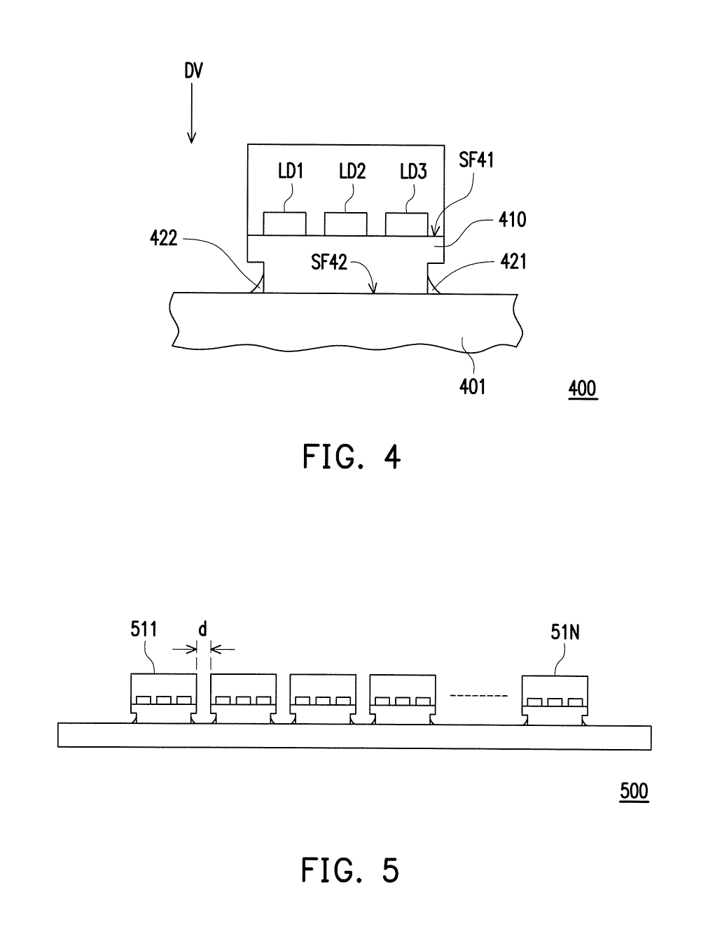

Referring to FIG. 4, FIG. 4 is a structural schematic diagram of a display pixel according to an embodiment of the invention. The display pixel 400 includes a package base 410 and one or a plurality of LEDs LD1-LD3. The package base 410 has surfaces SF41 and SF42 opposite to each other. The LEDs LD1-LD3 are disposed on the surface SF41, where the LEDs LD1-LD3 may provide at least one type of light-emitting wavelength. It should be noted that the one or plurality of LEDs LD1-LD3 can be composed of compound semiconductor LED chips, laser LED chips or organic LEDs for high color saturation and color rendering index. The surface SF42 of the package base 410 can be configured on the circuit substrate 401, and is bonded to the circuit substrate 401 through conductive adhesive materials 421 and 422. The conductive adhesive materials 421 and 422 can be solder paste or any conductive adhesive material known by those skilled in the art.

It should be noted that an area of the surface SF41 of the package base 410 used for carrying the LEDs LD1-LD3 is greater than an area of the surface SF42 of the package base 410. Namely, by inspecting the display pixel 400 along a direction DV, the bottom of the package base 410 is completely covered by the surface SF41 of the package base 410. Further, a projection of the surface SF41 of the package base 410 on the circuit substrate 401 completely covers the surface SF42 of the package base 410, and even completely covers the conductive adhesive materials 421 and 422. In this way, the influence of the conductive adhesive materials 421 and 422 on the contrast of the LED display apparatus is decreased, and the LED display apparatus of the invention is unnecessary to configure a mask. Referring to FIG. 5, FIG. 5 is a schematic diagram of a display matrix according to an embodiment of the invention. Under the premise that the display matrix 500 is unnecessary to configure a mask, a distance d between the display pixels 511-51N can be decreased, so as to effectively increase a fill factor of the display area.

It should be noted that the LEDs included in the display pixel of the invention can be a flip-chip package, a surface mounted device, a epoxy molding compound lead frame, a chip scale package or a chip on board package, and each of the LEDs may have at least one light-emitting wavelength.

In summary, the invention provides the interface circuit to serve as an integration interface of the driving circuit, which may effectively decrease the complexity of the system design of the client. Moreover, the first surface of the package base that has a larger area may cover the second surface of the package base in a visual effect, so that a display contrast of the LED display apparatus is improved, and a distance between the LED elements is decreased to increase the fill factor of the display area.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. A light-emitting diode display apparatus, comprising:
a circuit substrate;
a display matrix, disposed on the circuit substrate, and having a plurality of display pixels;
a driving circuit, disposed on the circuit substrate, and electrically coupled to the display matrix, wherein the driving circuit has at least one driver, and the driver has a programmable planning area; and
an interface circuit, disposed on the circuit substrate, electrically coupled to the driving circuit, and configured to receive input information, and transporting the input information to the at least one driving circuit.

2. The light-emitting diode display apparatus as claimed in claim 1, wherein the circuit substrate has a first surface and a second surface opposite to each other, the display matrix is disposed on the first surface of the circuit substrate, and the driving circuit and the interface circuit are disposed on the second surface of the circuit substrate.

3. The light-emitting diode display apparatus as claimed in claim 1, wherein the interface circuit is a serial interface circuit.

4. The light-emitting diode display apparatus as claimed in claim 1, wherein each of the display pixels emits a monochromatic light or a polychromatic light.

5. The light-emitting diode display apparatus as claimed in claim 1, wherein each of the display pixels comprises at least one light-emitting diode, the at least one light-emitting diode has at least one light-emitting wavelength.

6. The light-emitting diode display apparatus as claimed in claim 5, wherein the light-emitting diode is a flip-chip package, a surface mounted device, a epoxy molding compound lead frame, a chip scale package or a chip on board package.

7. The light-emitting diode display apparatus as claimed in claim 1, wherein the driver comprises at least one horizontal driver or at least one vertical driver.

8. The light-emitting diode display apparatus as claimed in claim 1, wherein the display pixel comprises:
a package base, having a first surface and a second surface opposite to each other, the first surface of the package base being configured with light-emitting diodes with at least one light-emitting wavelength, the second surface of the package base being bonded to the circuit board, wherein an area of the first surface of the package base is greater than or equal to an area of the second surface of the package base.

9. The light-emitting diode display apparatus as claimed in claim 8, wherein a projection of the first surface of the package base on the circuit board completely covers the second surface of the package base.

10. The light-emitting diode display apparatus as claimed in claim 8, wherein the second surface of the package base is bonded to the circuit substrate through a conductive adhesive material.

11. A light-emitting diode display apparatus, comprising:
a circuit substrate;
a display matrix, disposed on the circuit substrate, and having a plurality of display pixels, each of the display pixels comprising:
a package base, having a first surface and a second surface opposite to each other, the first surface of the package base being configured with light-emitting diodes with at least one light-emitting wavelengths, the second surface of the package base being bonded to the circuit board, wherein an area of the first surface of the package base is greater than or equal to an area of the second surface of the package base;
a driving circuit, disposed on the circuit substrate, comprising a plurality of drivers to drive the display pixels, and each of the drivers comprising a programmable planning area; and
an interface circuit, disposed on the circuit substrate, and electrically coupled to the driving circuit.

12. The light-emitting diode display apparatus as claimed in claim 11, wherein a projection of the first surface of the package base on the circuit board completely covers the second surface of the package base.

13. The light-emitting diode display apparatus as claimed in claim 11, wherein the second surface of the package base is bonded to the circuit substrate through a conductive adhesive material.

14. The light-emitting diode display apparatus as claimed in claim 11, wherein the light-emitting diode is a flip-chip package, a surface mounted device, a epoxy molding compound lead frame, a chip scale package or a chip on board package.
